(19) United States
(12) Patent Application Publication
(10) Pub. No.: US 2025/0004173 A1
(43) Pub. Date: Jan. 2, 2025

(54) METHOD OF MANUFACTURING A META-OPTICAL ELEMENT, A META-OPTICAL ELEMENT MANUFACTURED USING THE SAME, AND AN OPTICAL DEVICE INCLUDING THE META-OPTICAL ELEMENT

(71) Applicants: Samsung Display Co., LTD., Yongin-si (KR); POSTECH RESEARCH AND BUSINESS DEVELOPMENT FOUNDATION, Pohang-si (KR)

(72) Inventors: JAEHO YOU, Yongin-si (KR); Junsuk Rho, Pohang-si (KR); BEOMSHIK KIM, Yongin-si (KR); YOUNGCHAN KIM, Yongin-si (KR); Sunae So, Pohang-si (KR); Dong Kyo Oh, Pohang-si (KR); Seokho Lee, Pohang-si (KR); Chihun Lee, Pohang-si (KR)

(73) Assignees: Samsung Display Co., LTD., Yongin-si (KR); POSTECH RESEARCH AND BUSINESS DEVELOPMENT FOUNDATION, Pohang-si (KR)

(21) Appl. No.: 18/760,345

(22) Filed: Jul. 1, 2024

(30) Foreign Application Priority Data
Jun. 30, 2023 (KR) 10-2023-0085299

(51) Int. Cl. G02B 1/00

(52) U.S. Cl. CPC G02B 1/005; G02B 2207/101

(57) ABSTRACT

A method of manufacturing a meta-optical element includes propagating light with random phase distribution toward a light collecting surface, obtaining a simulation intensity of the light at the light collecting surface through simulation, generating an error function based on an error data which is a difference between the simulation intensity of the light and an ideal intensity of the light, obtaining an optimal phase distribution of the light which outputs a minimum function value of the error function by applying a gradient descent, and forming a meta-optical element that implements the optimal phase distribution.

### CROSS-REFERENCE TO RELATED APPLICATION(S)

This application claims priority to and benefits of Korean Patent Application No. 10-2023-0085299 under 35 U.S.C. § 119, filed on Jun. 30, 2023, in the Korean Intellectual Property Office, the entire contents of which are incorporated herein by reference.

### BACKGROUND

### 1. Technical Field

The disclosure relates to a method of manufacturing a meta-optical element, a meta-optical element manufactured using the same, and an optical device including the meta-optical element. By way of example, the disclosure relates to an optical device which provides visual information, a meta-optical element included in the optical device, and a method of manufacturing the meta-optical element.

### 2. Description of the Related Art

As information technology develops, the importance of a display device as a connection medium between a user and information is being highlighted. For example, the use of display devices such as a liquid crystal display device (LCD), an organic light emitting display device (OLED), a plasma display device (PDP), and a quantum dot display device is increasing.

Recently, there has been a demand for miniaturization of the display device. Accordingly, attempts to implement flat and thin optical devices based on a meta-surface are continuing.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a method of manufacturing a meta-optical element that enables optimized design of a meta-optical element with improved chromatic aberration.

Embodiments provide a meta-optical element with improved chromatic aberration.

Embodiments provide an optical device including the meta-optical element.

A method of manufacturing a meta-optical element according to an embodiment may include propagating light with random phase distribution toward a light collecting surface; obtaining a simulation intensity of the light at the light collecting surface through simulation; generating an error function based on an error data, the error data being a difference between the simulation intensity of the light and an ideal intensity of the light; obtaining an optimal phase distribution of the light which outputs a minimum function value of the error function by applying a gradient descent, and forming a meta-optical element that implements the optimal phase distribution.

In an embodiment, the obtaining of the optimal phase distribution of the light by applying the gradient descent may include calculating a gradient in a direction in which an output result of the error function minimizes a function value.

In an embodiment, an error function optimization process in which calculating a gradient again by adding a value obtained by multiplying a previously calculated gradient by an adjustment parameter to a variable of the error function may be performed in the calculating the gradient, and the error function optimization process may be repeatedly performed until the minimum function value of the error function is output.

In an embodiment, the propagating of the light toward the light collecting surface, the obtaining of the simulation intensity, the generating of the error function, and the obtaining of the optimal phase distribution may be repeatedly performed by changing a wavelength of the light.

In an embodiment, the optimal phase distribution may be a phase distribution that outputs the minimum function value of the error function for each wavelength of the light.

In an embodiment, the optimal phase distribution in case that a wavelength band of the light is a red wavelength band, the optimal phase distribution in case that a wavelength band of the light is a green wavelength band, and the optimal phase distribution in case that a wavelength band of the light is a blue wavelength band may be all the same.

In an embodiment, the optimal phase distribution may be a single-phase distribution.

In an embodiment, the forming of the meta-optical element may include disposing nanostructures on a substrate to form a geometrical phased array.

In an embodiment, the geometrical phased array may be a Pancharatnam-Berry phased array.

In an embodiment, an arrangement direction of one of the nanostructures may be different from an arrangement direction of at least another one of the nanostructures.

In an embodiment, the nanostructures may have a same structure.

In an embodiment, the nanostructures may be formed of a material having a refractive index different from a refractive index of the substrate.

A meta-optical element according to an embodiment may include a substrate; and nanostructures in a geometric phased array on the substrate and having a same structure.

In an embodiment, the geometrical phased array may be a Pancharatnam-Berry phased array.

In an embodiment, an arrangement direction of one of the nanostructures may be different from an arrangement direction of at least another one of the nanostructures.

In an embodiment, the nanostructures may be disposed on the substrate to collect a light in a red wavelength band, a light in a green wavelength band, and a light in a blue wavelength band on a same light collecting surface.

In an embodiment, a refractive index of each of the nanostructures may be different from a refractive index of the substrate.

The optical device according to an embodiment may include a light source part which emits light and a meta-optical element disposed on a path of light emitted from the light source part, and the meta-optical element may include a substrate and nanostructures disposed in a geometric phased array on the substrate and having a same structure.

In an embodiment, an arrangement direction of one of the nanostructures may be different from an arrangement direction of at least another one of the nanostructures.

In an embodiment, the nanostructures may be disposed on the substrate to collect a light in a red wavelength band, a light in a green wavelength band, and a light in a blue wavelength band on a same light collecting surface.

In an embodiment, the light source part may include a first electrode, a second electrode disposed on the first electrode and facing the first electrode, and an emission layer disposed between the first electrode and the second electrode and including a light emitting material.

In a meta-optical element according to embodiments, the meta-optical element may include the nanostructures in a geometric phased array and having the same structure as each other. Accordingly, differences in characteristics of light passing through each position of the meta-optical element may be reduced or prevented. The meta-optical element may collect a light in a red wavelength band, a light in a green wavelength band, and a light in a blue wavelength band on substantially the same light collecting surface. Accordingly, chromatic aberration may be improved.

According to the method of manufacturing the meta-optical element according to embodiments, since it is possible to obtain a single optimal phase distribution that is equally applied to light in various wavelength bands by applying a gradient descent, it may not be required to obtain multiple phase distributions for each wavelength. Therefore, an optimized design of the meta-optical element MOE with improved chromatic aberration may be possible. It is to be understood that both the foregoing general description and the following detailed description are by way of example and explanatory and are intended to provide further explanation of the disclosure as claimed.

### BRIEF DESCRIPTION OF THE DRAWINGS

Illustrative, non-limiting embodiments will be more clearly understood from the following detailed description taken in conjunction with the accompanying drawings in which:

FIG. 1 is a schematic perspective view illustrating a meta-optical element according to an embodiment.

FIG. 2 is a flowchart illustrating a method of manufacturing the meta-optical element of FIG. 1.

FIG. 3 is a graph illustrating a simulation intensity and an ideal intensity of light considered in the method of manufacturing the meta-optical element of FIG. 2.

FIG. 4 is a view illustrating an optical device including the meta-optical element of FIG. 1 according to an embodiment.

FIG. 5 is a view illustrating a light source part included in the optical device of FIG. 4 according to an embodiment.

FIG. 6 is a block diagram illustrating an electronic device according to embodiments.

FIG. 7 is a diagram illustrating a case in which the electronic device of FIG. 6 is implemented as a smart phone.

### DETAILED DESCRIPTION OF THE EMBODIMENTS

The disclosure now will be described more fully hereinafter with reference to the accompanying drawings, in which various embodiments are shown. This disclosure may, however, be embodied in many different forms, and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

For the embodiments of the disclosure disclosed in the text, structural or functional descriptions are described for the purpose of explaining the embodiments of the disclosure, and the embodiments of the disclosure may be implemented in various forms and should not be construed as being limited to the embodiments described herein.

Since the disclosure can have various changes and various forms, embodiments will be illustrated in the drawings and described in detail in the text. However, this is not intended to limit the disclosure to a specific form disclosed, and should be understood to include all modifications, equivalents, and substitutes included in the spirit and scope of the disclosure.

In the drawings, sizes, thicknesses, ratios, and dimensions of the elements may be exaggerated for ease of description and for clarity. Like numbers refer to like elements throughout.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Terms such as first and second may be used to describe various components, but the components should not be limited by the terms. The terms may be used for the purpose of distinguishing one component from another. For example, a first element may be termed a second element, and similarly, a second element may be termed a first element, without departing from the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

Steps comprising a method may be performed in any suitable order unless explicitly stated that they must be performed in an order described. Use of all terms is simply for explaining a technical idea in detail, and unless limited by the claims, the scope of rights is not limited by these terms.

Terms used in this application are used to describe embodiments, and are not intended to limit the disclosure.

As used herein, the singular forms, “a,” “an,” and “the” are intended to include the plural forms as well, unless the context clearly indicates otherwise.

In this application, terms such as “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

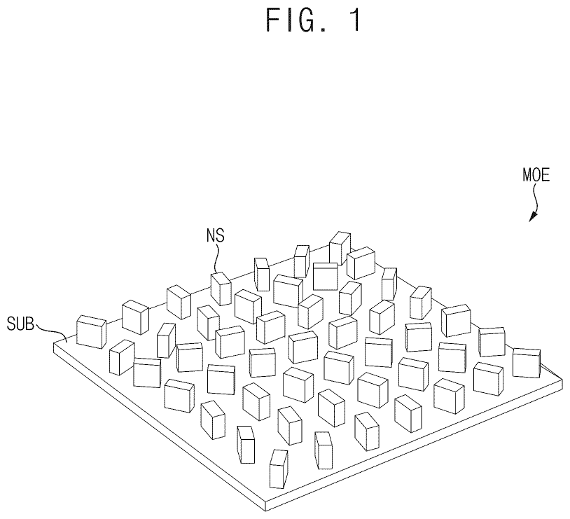

FIG. 1 is a schematic perspective view illustrating a meta-optical element according to an embodiment.

Referring to FIG. 1, a meta-optical element MOE according to an embodiment may be a diffractive element that modulates a phase of incident light. For example, the meta-optical element MOE may converge the incident light. The meta-optical element MOE may include a substrate SUB and nanostructures NS.

The nanostructures NS may form a refractive index distribution representing a phase retardation profile for implementing desired optical performance for light in a desired wavelength band.

The substrate SUB may support the nanostructures NS. In an embodiment, the substrate SUB may be a transparent substrate. For example, the substrate SUB may be a glass substrate, a quartz substrate, a silicon oxide (SiO2) substrate, or a polymer substrate including polymer such as PET (polyethylene terephthalate), PMMA (polymethyl methacrylate), or PDMS (polydimethylsiloxane). However, the disclosure is not necessarily limited thereto.

The nanostructures NS may include c-Si, p-Si, a-Si, III-V compound semiconductors (GaP, GaN, GaAs, etc.), SiC, TiO₂, SiN, or the like within the spirit and the scope of the disclosure. These can be used alone or in combination with each other.

The nanostructures NS may be disposed on the substrate SUB to form a geometrical phased array. For example, the nanostructures NS may be arranged (or disposed) on the substrate SUB to form a geometric phase lens. However, the disclosure is not necessarily limited thereto. In an embodiment, the geometric phased array may be a Pancharatnam-Berry phased array.

By way of example, an arrangement direction of one of the nanostructures NS may be different from an arrangement direction of at least another one of the nanostructures NS.

For example, each of the nanostructures NS may be arranged at various angles with respect to a horizontal direction and/or a vertical direction on the substrate SUB. Accordingly, the nanostructures NS may be arranged to form the geometrical phased array on the substrate SUB.

The nanostructures NS disposed on the substrate SUB may have the same structure. Here, a term ‘structure’ may mean a shape, a size, and a material of each of the nanostructures NS. By way of example, the term ‘structure’ may be a term that comprehensively refers to the remaining characteristics excluding an arrangement direction of each of the nanostructures NS.

For example, the nanostructures NS disposed on the substrate SUB may have the same characteristics except for an arrangement direction. For example, as illustrated in FIG. 1, the nanostructures NS may have a square pillar shape with the same side length and the same height.

However, the disclosure is not necessarily limited thereto. For example, the nanostructures NS may have a cylindrical shape with the same diameter and the same height. For example, the nanostructures NS may have the same pillar shape, and a cross-sectional shape may be polygonal, elliptical, or other various shapes.

In an embodiment, a refractive index of each of the nanostructures NS and a refractive index of the substrate SUB may be different from each other. For example, the nanostructures NS may be formed to have a higher refractive index than the substrate SUB. However, the disclosure is not necessarily limited thereto, and the nanostructures NS may be formed to have a lower refractive index than the substrate SUB.

Light passing through the meta-optical element MOE may be focused on substantially the same light collecting surface regardless of a wavelength band. For example, in all cases where the wavelength band of light passing through the meta-optical element MOE is a red wavelength band, a green wavelength band, and a blue wavelength band, the light passing through the meta-optical element MOE may be collected on substantially the same light collecting surface.

Even in a case where the light passing through the meta-optical element MOE is mixed light that is a mixture of a light in the red wavelength band, a light in the green wavelength band, and a light in the blue wavelength band, the light passing through the meta-optical element MOE may be substantially collected on the same light collecting surface.

In the meta-optical element MOE according to embodiments, the meta-optical element MOE may include the nanostructures NS arranged to form a geometric phased array and having the same structure as each other. Accordingly, differences in characteristics of light passing through each position of the meta-optical element MOE may be reduced or prevented. The meta-optical element MOE may collect a light in a red wavelength band, a light in a green wavelength band, and a light in a blue wavelength band on substantially the same light collecting surface. Accordingly, chromatic aberration may be improved.

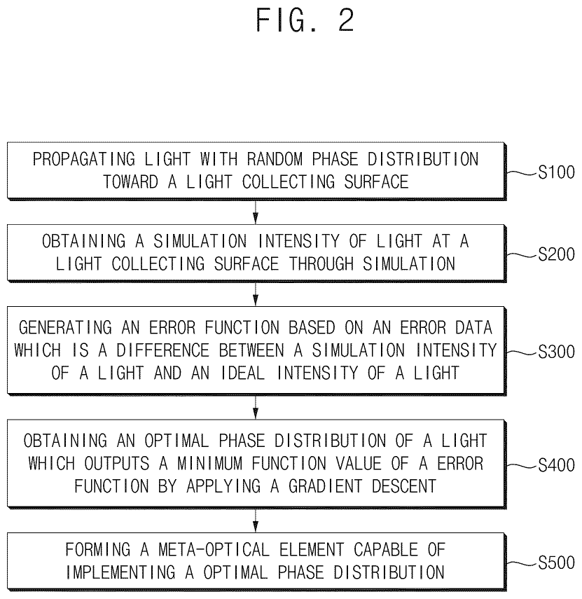

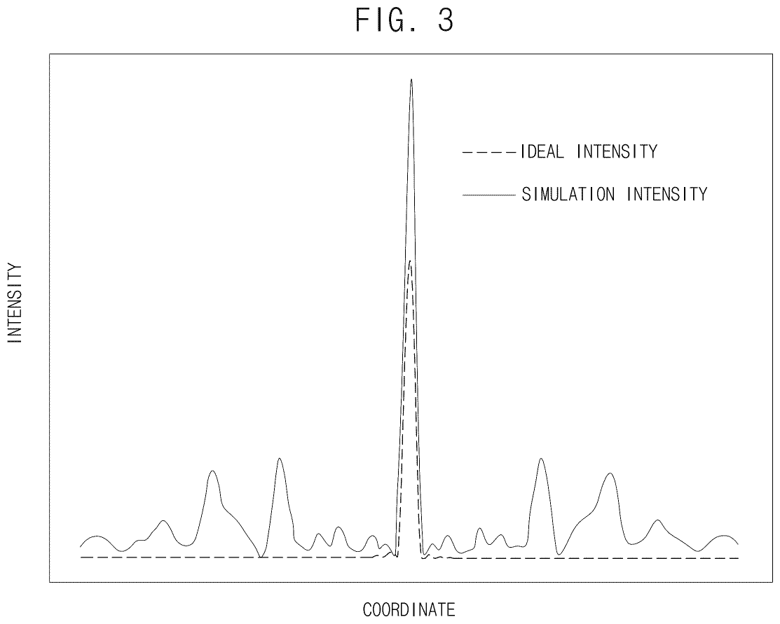

FIG. 2 is a flowchart illustrating a method of manufacturing the meta-optical element of FIG. 1. FIG. 3 is a graph illustrating a simulation intensity and an ideal intensity of light considered in the method of manufacturing the meta-optical element of FIG. 2.

Hereinafter, with further reference to FIGS. 2 and 3, a method of manufacturing the meta-optical element MOE according to an embodiment will be described.

Referring to FIG. 2, the method of manufacturing the meta-optical element MOE according to an embodiment may include propagating light with random phase distribution toward a light collecting surface (S100), obtaining a simulation intensity of the light at the light collecting surface through simulation (S200), generating an error function based on an error data which is a difference between the simulation intensity of the light and an ideal intensity of the light (S300), obtaining an optimal phase distribution of the light which outputs a minimum function value of the error function by applying a gradient descent (S400), and forming a meta-optical element capable of implementing the optimal phase distribution (S500).

According to the method of manufacturing the meta-optical element MOE according to an embodiment, the light having the random phase distribution may be propagated toward the light collecting surface (S100). For example, the light may be propagated to the light collecting surface by a light source, or the like within the spirit and the scope of the disclosure.

The light propagating to the light collecting surface may have a selectable wavelength band. For example, the wavelength band of the light may be in a range of about 420 nm to about 480 nm, and as another example, the wavelength band of the light may be in a range of about 500 nm to about 580 nm, and as another example, the wavelength band of the light may be in a range of about 600 nm to about 670 nm.

For example, for example, the light propagating to the light collecting surface may have a blue wavelength band, and as another example, the light propagating to the light collecting surface may have a green wavelength band, and for another example, the light propagating to the light collecting surface may have a red wavelength band.

Thereafter, the simulation intensity of the light at the light collecting surface may be obtained (S200). For example, simulation may be performed using any simulation tool to obtain the simulated intensity of the light propagated to the light collecting surface.

For example, as illustrated in FIG. 3, the simulation intensity of the light propagating to the light collecting surface may vary depending on coordinates on the light collecting surface. The simulation intensity of light illustrated in FIG. 3 is only an example and may be changed in various ways.

Thereafter, an error function may be generated based on an error data which is a difference between the simulation intensity of the light and the ideal intensity of the light (S300).

At this time, the ideal intensity of the light may mean an intensity in case that the light forms an image up to a diffraction limit, referred to as an airy disk, on the light collecting surface. For example, the ideal intensity of light may appear as illustrated in a graph of FIG. 3. For example, the ideal intensity of the light may be a form concentrated in a center of the light collecting surface.

The error data may be a data obtained by calculating the difference between the simulation intensity of the light and the ideal intensity of the light, according to coordinates on the light collecting surface. For example, the error data may be a data obtained by quantifying a degree to which the simulation intensity of the light deviates from the ideal intensity of the light.

After obtaining the error data, the error function may be generated based on the random phase distribution and the error data. For example, the error function may be generated using the random phase distribution as a parameter.

Thereafter, gradient descent may be applied to obtain the optimal phase distribution of the light which outputs the minimum function value of the error function (S400).

At this time, gradient descent is one of the methods used in case that learning a machine learning and a deep learning algorithms, and is a method of finding the minimum function value through several steps on the error function.

For example, the gradient descent may include a process of reducing errors by obtaining a gradient for an initial point in time and converging the gradient through a process of moving in an opposite direction of the gradient. In other words, the obtaining the optimal phase distribution of the light may include calculating a gradient in a direction in which an output result of the error function minimizes a function value.

For example, if a gradient of a current position of the error function is negative, the gradient may be converged by increasing a parameter (for example, the random phase distribution) of the error function. If a gradient of a current position of the error function is positive, the gradient may be converged by decreasing a parameter (for example, the random phase distribution) of the error function. Accordingly, the minimum function value of the error function may be found, and a phase distribution of the light which outputs the minimum function value of the error function may be obtained. For example, the optimal phase distribution of the light may mean a phase distribution in which the function value of the error function is minimized.

By way of example, in the calculating the gradient, an error function optimization process in which calculating a gradient again by adding a value obtained by multiplying a previously calculated gradient by an adjustment parameter to a variable (e.g., phase distribution) of the error function may be performed. The error function optimization process may be repeatedly performed until the minimum function value of the error function is output.

In other words, according to the method of manufacturing the meta-optical element MOE according to embodiments, the random phase distribution of the light may be continuously updated by applying the gradient descent method, the propagating the light toward the light collecting surface (S100), the obtaining the simulation intensity of the light (S200), the generating the error function (S300), and the obtaining the optimal phase distribution of the light (S400) may be repeatedly performed.

In an embodiment, the propagating the light toward the light collecting surface (S100), the obtaining the simulation intensity of the light (S200), the generating the error function (S300), and the obtaining the optimal phase distribution of the light (S400) may be repeatedly performed by changing a wavelength of the light.

For example, according to the method of manufacturing the meta-optical element MOE according to embodiments, since the random phase distribution of the light is continuously updated by applying the gradient descent method, and the propagating the light toward the light collecting surface (S100), the obtaining the simulation intensity of the light (S200), the generating the error function (S300), and the obtaining the optimal phase distribution of the light (S400) is repeatedly performed, the propagating the light toward the light collecting surface (S100), the obtaining the simulation intensity of the light (S200), the generating the error function (S300), and the obtaining the optimal phase distribution of the light (S400) may be repeatedly performed by changing a wavelength of the light.

By way of example, the propagating the light toward the light collecting surface (S100), the obtaining the simulation intensity of the light (S200), the generating the error function (S300), and the obtaining the optimal phase distribution of the light (S400) may be repeatedly performed by changing a wavelength band of the light.

For example, the propagating the light toward the light collecting surface (S100), the obtaining the simulation intensity of the light (S200), the generating the error function (S300), and the obtaining the optimal phase distribution of the light (S400) may be performed equally in case that the light has a wavelength band in a range of about 420 nm to about 480 nm, in case that the light has a wavelength band in a range of about 500 nm to about 580 nm, and in case that the light has a wavelength band in a range of about 600 nm to about 670 nm

In other words, the propagating the light toward the light collecting surface (S100), the obtaining the simulation intensity of the light (S200), the generating the error function (S300), and the obtaining the optimal phase distribution of the light (S400) may be performed equally in case that the light has a blue wavelength band, in case that the light has a green wavelength band, and in case that the light has a red wavelength band.

By way of example, targeting the light having a blue wavelength band, the propagating the light toward the light collecting surface (S100), the obtaining the simulation intensity of the light (S200), the generating the error function (S300), and the obtaining the optimal phase distribution of the light (S400) may be repeatedly performed for obtaining a phase distribution of the light which outputs the minimum function value of the error function.

Thereafter, targeting the light having a green wavelength band, the propagating the light toward the light collecting surface (S100), the obtaining the simulation intensity of the light (S200), the generating the error function (S300), and the obtaining the optimal phase distribution of the light (S400) may be repeatedly performed for obtaining a phase distribution of the light which outputs the minimum function value of the error function.

Thereafter, targeting the light having a red wavelength band, the propagating the light toward the light collecting surface (S100), the obtaining the simulation intensity of the light (S200), the generating the error function (S300), and the obtaining the optimal phase distribution of the light (S400) may be repeatedly performed for obtaining a phase distribution of the light which outputs the minimum function value of the error function.

Based on this, a phase distribution of the light which satisfies all of a phase distribution of the light which outputs the minimum function value of the error function in case that the light has a blue wavelength band, a phase distribution of the light which outputs the minimum function value of the error function in case that the light has a green wavelength band, and a phase distribution of the light which outputs the minimum function value of the error function in case that the light has a red wavelength band. Therefore, the optimal phase distribution may be a single-phase distribution.

For example, the optimal phase distribution may be a phase distribution capable of outputting the minimum function value of the error function for each wavelength of the light. In other words, the optimal phase distribution in case that a wavelength band of the light is a red wavelength band, the optimal phase distribution in case that a wavelength band of the light is a green wavelength band, and the optimal phase distribution in case that a wavelength band of the light is a blue wavelength band are all the same.

Thereafter, the meta-optical element capable of implementing the optimal phase distribution may be formed (S500).

Referring to FIG. 1 together, the forming of the meta-optical element (S500) may include arranging the nanostructures NS on the substrate SUB. In an embodiment, the meta-optical element MOE may be formed according to a selectable semiconductor process. For example, to form the meta-optical element MOE, a material layer that will become the nanostructures NS may be stacked on the substrate SUB, and a process of patterning the material layer may be performed.

The substrate SUB may be formed as a glass substrate, a quartz substrate, a silicon oxide (SiO2) substrate, or a polymer substrate including polymer such as PET (polyethylene terephthalate), PMMA (polymethyl methacrylate), or PDMS (polydimethylsiloxane).

The nanostructures NS may be formed by c-Si, p-Si, a-Si, III-V compound semiconductors (GaP, GaN, GaAs, etc.), SiC, TiO₂, SiN, or the like within the spirit and the scope of the disclosure.

In an embodiment, the substrate SUB and the nanostructures NS may be formed such that a refractive index of each of the nanostructures NS and a refractive index of the substrate SUB is different. For example, the nanostructures NS may be formed to have a higher refractive index than the substrate SUB. However, the disclosure is not necessarily limited thereto, and the nanostructures NS may be formed to have a lower refractive index than the substrate SUB.

The nanostructures NS may be arranged on the substrate SUB such that the meta-optical element MOE can implement the optimal phase distribution obtained through the obtaining an optimal phase distribution of the light (S400). In other words, in the forming the meta-optical element (S500), the nanostructures NS may be arranged on the substrate SUB such that the meta-optical element MOE can implement a single optimal phase distribution.

Accordingly, light passing through the meta-optical element MOE may be focused on substantially the same light collecting surface regardless of a wavelength band. For example, in all cases where the wavelength band of light passing through the meta-optical element MOE is a red wavelength band, a green wavelength band, and a blue wavelength band, the light passing through the meta-optical element MOE may be collected on substantially the same light collecting surface. Even in a case where the light passing through the meta-optical element MOE is mixed light that is a mixture of a light in the red wavelength band, a light in the green wavelength band, and a light in the blue wavelength band, the light passing through the meta-optical element MOE may be substantially collected on the same light collecting surface.

For example, in the forming the meta-optical element (S500), the nanostructures NS may be arranged to form a geometrical phased array on the substrate SUB. For example, the nanostructures NS may be arranged to form a geometric phase lens on the substrate SUB. However, the disclosure is not necessarily limited thereto. In an embodiment, the geometric phased array may be a Pancharatnam-Berry phased array.

By way of example, the nanostructures NS may be formed such that an arrangement direction of one of the nanostructures NS may be different from an arrangement direction of at least another one of the nanostructures NS. For example, each of the nanostructures NS may be arranged at various angles with respect to a horizontal direction and/or a vertical direction on the substrate SUB. Accordingly, the nanostructures NS may be arranged to form the geometrical phased array on the substrate SUB.

The nanostructures NS disposed on the substrate SUB may have the same structure. As described above, a term ‘structure’ may mean a shape, a size, and a material of each of the nanostructures NS. By way of example, the term ‘structure’ may be a term that comprehensively refers to the remaining characteristics excluding an arrangement direction of each of the nanostructures NS.

For example, the nanostructures NS disposed on the substrate SUB may have the same characteristics except for an arrangement direction. For example, as illustrated in FIG. 1, the nanostructures NS may have a square pillar shape with the same side length and the same height.

However, the disclosure is not necessarily limited thereto. For example, the nanostructures NS may have a cylindrical shape with the same diameter and the same height. For example, the nanostructures NS may have the same pillar shape, and a cross-sectional shape may be polygonal, elliptical, or other various shapes.

According to the method of manufacturing the meta-optical element MOE according to embodiments, a single optimal phase distribution which is equally applied to light in various wavelength bands may be obtained by applying a gradient descent, and the meta-optical element MOE capable of implementing the optimal phase distribution may be formed. Accordingly, the meta-optical element MOE that can function equally for light of various wavelength bands may be formed. For example, the meta-optical element MOE may collect a light in a red wavelength band, a light in a green wavelength band, and a light in a blue wavelength band on substantially the same light collecting surface. Accordingly, chromatic aberration may be improved.

According to the method of manufacturing the meta-optical element MOE according to embodiments, since it is possible to obtain a single optimal phase distribution that is equally applied to light in various wavelength bands by applying a gradient descent, it may not be required to obtain multiple phase distributions for each wavelength. Therefore, an optimized design of the meta-optical element MOE with improved chromatic aberration may be possible.

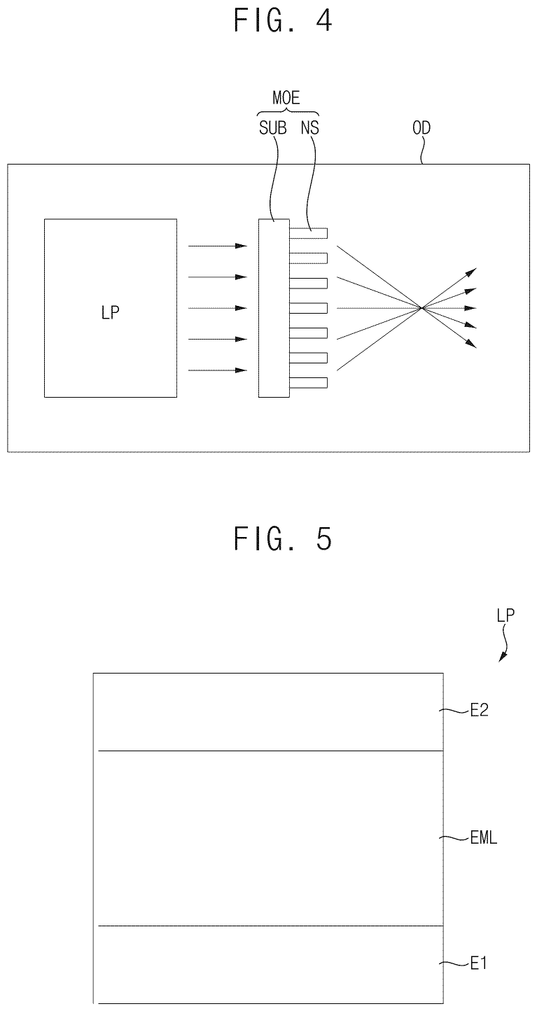

FIG. 4 is a view illustrating an optical device including the meta-optical element of FIG. 1 according to an embodiment. FIG. 5 is a view illustrating a light source part included in the optical device of FIG. 4 according to an embodiment.

Referring to FIG. 4, an optical device OD according to an embodiment may include the meta-optical element MOE. In an embodiment, the optical device OD may further include a light source part LP which emits light.

The meta-optical element MOE may be disposed in the optical device OD on a path of light emitted from the light source part LP. For example, the meta-optical element MOE may collect light emitted from the light source part LP. For example, the meta-optical element MOE may function as a condensing lens. However, the disclosure is not necessarily limited thereto, and the meta-optical element MOE may function as a beam deflector or beam shaper.

In an embodiment, the light source part LP may be a light emitting element that emits light. For example, the light source part LP may be an organic light emitting element, an inorganic light emitting element, an organic-inorganic light emitting element, a quantum dot light emitting element, a quantum rod light emitting element, a micro light emitting element, a nano light emitting element, or the like within the spirit and the scope of the disclosure.

The light source part LP may include a first electrode E1, an emission layer EML, and a second electrode E2 sequentially stacked each other. For example, the light source part LP may be a light emitting element that emits light from the emission layer EML by a voltage difference between the first electrode E1 and the second electrode E2. For example, the light source part LP may be a light emitting element in which the first electrode E1 is an anode and the second electrode E2 is a cathode. For another example, the light source part LP may be an inverted type light emitting element in which the first electrode E1 is a cathode and the second electrode E2 is an anode.

Each of the first electrode E1 and the second electrode E2 may include a metal, alloy, conductive metal oxide, transparent conductive material, or the like within the spirit and the scope of the disclosure. The emission layer EML may include a light emitting material. For example, the emission layer EML may include an organic light emitting material, an inorganic light emitting material, quantum dots, quantum rods, or the like within the spirit and the scope of the disclosure.

In an embodiment, the meta-optical element MOE may include the substrate SUB and the nanostructures NS arranged to form a geometric phased array and having the same structure as each other. However, since this has been explained with reference to FIG. 1, redundant description thereof will be omitted.

The optical device OD may further include components other than the meta-optical element MOE and the light source part LP illustrated in FIG. 4.

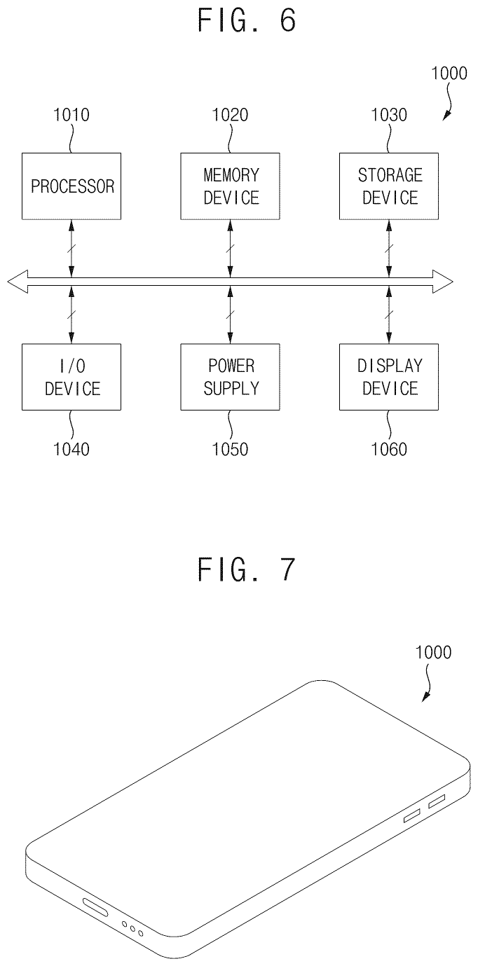

FIG. 6 is a block diagram illustrating an electronic device according to embodiments, and FIG. 7 is a diagram illustrating a case in which the electronic device of FIG. 6 is implemented as a smart phone.

Referring to FIGS. 6 and 7, an electronic device 1000 may include a processor 1010, a memory device 1020, a storage device 1030, an input/output device 1040, a power supply 1050, and a display device 1060. The display device 1060 may be the optical device of FIG. 4. For example, the display device 1060 may include the meta-optical element MOE of FIG. 1.

The electronic device 1000 may further include several ports capable of communicating with a video card, sound card, memory card, USB device, etc., or with other systems.

In an embodiment, as shown in FIG. 7, the electronic device 1000 may be implemented as a smart phone. However, this is only an example, and the electronic device 1000 is not limited thereto. For example, the electronic device 1000 may be implemented as a mobile phone, a video phone, a smart pad, a smart watch, a tablet PC, a vehicle navigation device, a computer monitor, a television, a laptop computer, a head mounted display device, or the like within the spirit and the scope of the disclosure.

The processor 1010 may perform selectable calculations or tasks. Depending on the embodiment, the processor 1010 may be a microprocessor, a central processing part, an application processor, or the like within the spirit and the scope of the disclosure. The processor 1010 may be connected to other components through an address bus, a control bus, and a data bus. According to an embodiment, the processor 1010 may be connected to an expansion bus such as a Peripheral Component Interconnect (PCI) bus.

The memory device 1020 may store data necessary for the operation of the electronic device 1000. For example, the memory device 1020 may include an Erasable Programmable Read-Only Memory (EPROM) device, an Electrically Erasable Programmable Read-Only Memory (EEPROM) device, a flash memory device, and a PRAM. (Phase Change Random Access Memory; PRAM) device, Resistance Random Access Memory (RRAM) device, Nano Floating Gate Memory (NFGM) device, Polymer Random Access Memory (PoRAM) device, MRAM (Magnetic Non-volatile memory devices such as Random Access Memory (MRAM), Ferroelectric Random Access Memory (FRAM) devices, and/or Dynamic Random Access Memory (DRAM) devices, Static Random Access Memory (SRAM) devices, a volatile memory device such as a mobile DRAM device, or the like within the spirit and the scope of the disclosure.

The storage device 1030 may include a solid state drive (SSD), a hard disk drive (HDD), a CD-ROM, or the like within the spirit and the scope of the disclosure.

The input/output device 1040 may include an input means such as a keyboard, a keypad, a touch pad, a touch screen, and a mouse, and an output means such as a speaker and a printer. Depending on embodiments, the display device 1060 may be included in the input/output device 1040.

The power supply 1050 may supply power necessary for operation of the electronic device 1000. For example, the power supply 1050 may be a power management integrated circuit (PMIC).

The display device 1060 may display an image corresponding to visual information of the electronic device 1000. The display device 1060 may be an organic light emitting display device or a quantum dot light emitting display device, but is not limited thereto. The display device 1060 may be connected to other components through the buses or other communication links.

In an embodiment, the display device 1060 may be the optical device OD described with reference to FIG. 4. For example, the display device 1060 may be an optical device that may include a substrate and nanostructures arranged to form a geometric phased array on the substrate and having the same structure as each other. However, since this has been explained with reference to FIGS. 1, 4, and 5, redundant description thereof will be omitted.

The disclosure should not be construed as being limited to the embodiments set forth herein. Rather, these embodiments are provided so that this disclosure will be thorough and complete and will fully convey the disclosure to those skilled in the art.

While the disclosure has been shown and described with reference to embodiments thereof, it will be understood by those of ordinary skill in the art that various changes in form and details may be made therein without departing from the spirit or scope of the disclosure and as defined by the following claims.

What is claimed is:

1. A method of manufacturing a meta-optical element comprising:
propagating light with random phase distribution toward a light collecting surface;
obtaining a simulation intensity of the light at the light collecting surface through simulation;
generating an error function based on an error data, the error data being a difference between the simulation intensity of the light and an ideal intensity of the light;
obtaining an optimal phase distribution of the light which outputs a minimum function value of the error function by applying a gradient descent; and
forming a meta-optical element that implements the optimal phase distribution.

2. The method of claim 1, wherein
the obtaining of the optimal phase distribution of the light by applying the gradient descent includes calculating a gradient in a direction in which an output result of the error function minimizes a function value,
an error function optimization process in which calculating a gradient again by adding a value obtained by multiplying a previously calculated gradient by an adjustment parameter to a variable of the error function is performed in the calculating of the gradient, and
the error function optimization process is repeatedly performed until the minimum function value of the error function is output.

3. The method of claim 1, wherein the propagating of the light toward the light collecting surface, the obtaining of the simulation intensity, the generating of the error function, and the obtaining of the optimal phase distribution are repeatedly performed by changing a wavelength of the light.

4. The method of claim 1, wherein the optimal phase distribution is a phase distribution that outputs the minimum function value of the error function for each wavelength of the light.

5. The method of claim 1, wherein the optimal phase distribution in case that a wavelength band of the light is a red wavelength band, the optimal phase distribution in case that a wavelength band of the light is a green wavelength band, and the optimal phase distribution in case that a wavelength band of the light is a blue wavelength band are all the same.

6. The method of claim 5, wherein the optimal phase distribution is a single-phase distribution.

7. The method of claim 1, wherein the forming of the meta-optical element includes disposing nanostructures on a substrate to form a geometrical phased array.

8. The method of claim 7, wherein the geometrical phased array is a Pancharatnam-Berry phased array.

9. The method of claim 7, wherein an arrangement direction of one of the nanostructures is different from an arrangement direction of at least another one of the nanostructures.

10. The method of claim 7, wherein the nanostructures have a same structure.

11. The method of claim 7, wherein the nanostructures are formed of a material having a refractive index different from a refractive index of the substrate.

12. A meta-optical element comprising:
a substrate; and
nanostructures in a geometric phased array on the substrate and having a same structure.

13. The meta-optical element of claim 12, wherein the geometrical phased array is a Pancharatnam-Berry phased array.

14. The meta-optical element of claim 12, wherein an arrangement direction of one of the nanostructures is different from an arrangement direction of at least another one of the nanostructures.

15. The meta-optical element of claim 12, wherein the nanostructures are disposed on the substrate to collect a light in a red wavelength band, a light in a green wavelength band, and a light in a blue wavelength band on a same light collecting surface.

16. The meta-optical element of claim 12, wherein a refractive index of each of the nanostructures is different from a refractive index of the substrate.

17. An optical device comprising:
a light source part which emits light; and
a meta-optical element disposed on a path of light emitted from the light source part, and
wherein the meta-optical element includes:
a substrate; and
nanostructures in a geometric phased array on the substrate and having a same structure.

18. The optical device of claim 17, wherein an arrangement direction of one of the nanostructures is different from an arrangement direction of at least another one of the nanostructures.

19. The optical device of claim 17, wherein the nanostructures are disposed on the substrate to collect a light in a red wavelength band, a light in a green wavelength band, and a light in a blue wavelength band on a same light collecting surface.

20. The optical device of claim 17, wherein the light source part includes:
a first electrode;
a second electrode disposed on the first electrode and facing the first electrode; and
an emission layer disposed between the first electrode and the second electrode and including a light emitting material.
